(19) United States
(12) Patent Application Publication
(10) Pub. No.: US 2026/0045763 A1
(43) Pub. Date: Feb. 12, 2026

(54) Driving Circuit

(71) Applicant: Artilux, Inc., Menlo Park, CA (US)

(72) Inventors: Kun-Yin Wang, Zhubei City (TW); Tze-Huei Kao, Zhubei City (TW); Che-Fu Liang, Zhubei City (TW)

(21) Appl. No.: 19/274,248

(22) Filed: Jul. 18, 2025

Related U.S. Application Data
(60) Provisional application No. 63/680,636, filed on Aug. 8, 2024.

(51) Int. Cl. H01S 5/042; H05B 45/345; H05B 45/397

(52) U.S. Cl. CPC H01S 5/042; H05B 45/345; H05B 45/397

(57) ABSTRACT

An example driving circuit includes a reference current source configured to provide a reference current. The driving circuit includes a first and a second transistor. The driving circuit includes a comparator coupling to the first transistor and the second transistor, and is configured to generate a comparison signal in response to a comparison of a voltage at a first node of the first transistor and a voltage at a first node of the second transistor. The driving circuit includes a voltage adjustment circuit coupling to the reference current source and the first transistor, and includes a third transistor and a conductive device coupling to the third transistor. The voltage adjustment circuit is configured to receive the comparison signal and adjust a voltage at the first node of the first transistor to approach a voltage at the first node of the second transistor.

### RELATED APPLICATIONS

The present application claims the benefit of and priority to U.S. Provisional Patent Application No. 63/680,636, filed Aug. 8, 2024, which is hereby incorporated by reference in its entirety FIELD

The present disclosure generally relates to driving circuitry that can be used in systems with low power supplies.

### BACKGROUND

Typical device ecosystems, in today's landscape, include portable electronic devices. Portable electronic devices include a certain level of energy consumption.

### SUMMARY

The present disclosure relates to a driving circuit for driving a device by a driving current, such as a light-emitting device (e.g., a laser diode, a light-emitting diode (LED), etc.), a MOS transistor, a circuit stage. Especially, the driving circuit can be used in systems with low power supplies.

An example aspect of the present disclosure is directed to a driving circuit configured to provide an output current to drive a device. The driving circuit includes a reference current source configured to provide a reference current. The driving circuit includes a first transistor including a first node, a second node, and a third node. The driving circuit includes a second transistor including a first node of the second transistor, a second node of the second transistor coupling to the second node of the first transistor, and a third node of the second transistor. The driving circuit includes a comparator coupling to the first transistor and the second transistor, and configured to generate a comparison signal in response to a comparison of a voltage at the first node of the first transistor and a voltage at the first node of the second transistor. The driving circuit includes a voltage adjustment circuit coupling to the reference current source and the first transistor, and includes a third transistor and a conductive device coupling to the third transistor. The voltage adjustment circuit is configured to receive the comparison signal and adjust a voltage at the first node of the first transistor to approach a voltage at the first node of the second transistor according to the comparison signal. The output current is equal to the reference current multiplied by a factor, and the factor is determined by a size ratio between the first transistor and the second transistor.

In some implementations, the comparator includes an amplifier, the amplifier includes two inputs coupling to the first node of the first transistor and the first node of the second transistor respectively, and an output coupling to the voltage adjustment circuit.

In some implementations, the comparison signal is generated by multiplying the voltage difference between the first node of the second transistor and the first node of the first transistor by a gain.

In some implementations, the third transistor includes a first node of the third transistor coupling to the reference current source, a second node of the third transistor coupling to the comparator to receive the comparison signal, and a third node of the third transistor coupling to the first node of the first transistor.

In some implementations, the third transistor includes a first node of the third transistor coupling to the second node of the first transistor and the second node of the second transistor.

In some implementations, the conductive device can be a variable resistor coupling to the third transistor in parallel and controlled by analog or digital method.

In some implementations, the conductive device can be a sixth transistor coupling to the third transistor in parallel.

In some implementations, a control signal can be applied to one of the nodes of the third transistor through the conductive device.

In some implementations, the voltage adjustment circuit couples to the second node of the first transistor and is configured to adjust a voltage at the second node of the first transistor according to the comparison signal.

In some implementations, the driving circuit includes a fourth transistor which is configured as a switch to control connection and disconnection between the driving circuit and the device.

In some implementations, the driving circuit includes a voltage shifter coupling to the device and the second transistor, wherein the voltage shifter is configured to adjust a voltage at the first node of the second transistor by shifting a voltage at an output of the driving circuit.

In some implementations, the voltage shifter includes a fourth transistor, and a control signal is applied on a second node of the fourth transistor to control the voltage difference between a first node and a third node of the fourth transistor.

In some implementations, the driving circuit includes a fifth transistor coupling to the fourth transistor to reduce a voltage drop induced by the fourth transistor.

In some implementations, the factor is determined by a size ratio of a width and a length of the second transistor and the first transistor.

In some implementations, the device is a light-emitting device.

In some implementations, the third node of the first transistor and the third node of the second transistor are coupled to a common voltage.

In another example aspect of the present disclosure is directed to a system configured to emit a light. The system includes a light-emitting device and a driving circuit coupling to the light-emitting device and configured to provide an output current to drive the light-emitting device. The driving circuit includes a reference current source configured to provide a reference current. The driving circuit includes a first transistor including a first node, a second node, and a third node. The driving circuit includes a second transistor including a first node of the second transistor, a second node of the second transistor coupling to the second node of the first transistor, and a third node of the second transistor. The driving circuit includes a comparator coupling to the first transistor and the second transistor, and configured to generate a comparison signal in response to a comparison of a voltage at the first node of the first transistor and a voltage at the first node of the second transistor. The driving circuit includes a voltage adjustment circuit coupling to the reference current source and the first transistor, and including a third transistor and a conductive device coupling to the third transistor. The voltage adjustment circuit is configured to receive the comparison signal and adjust a voltage at the first node of the first transistor to approach a voltage at the first node of the second transistor according to the comparison signal. The output current is equal to the reference current multiplied by a factor, and the factor is determined by a size ratio between the first transistor and the second transistor.

In some implementations, the comparator includes an amplifier, and the amplifier includes two inputs coupling to the first node of the first transistor and the first node of the second transistor respectively, and an output coupling to the voltage adjustment circuit.

In some implementations, the comparison signal is generated by multiplying the voltage difference between the first node of the second transistor and the first node of the first transistor by a gain.

In some implementations, the third transistor includes a first node coupling to the reference current source, a second node coupling to the comparator to receive the comparison signal, and a third node coupling to the first node of the first transistor.

Another aspect of the present disclosure is directed to a driving circuit configured to provide an output current to drive a device. The driving circuit includes a reference current source configured to provide a reference current. The driving circuit includes a first transistor including a first node, a second node, and a third node. The driving circuit includes a second transistor including a first node of the second transistor, a second node of the second transistor coupling to the second node of the first transistor, and a third node of the second transistor. The driving circuit includes a comparator coupling to the first transistor and the second transistor, and configured to generate a comparison signal in response to a comparison of a voltage at the first node of the first transistor and a voltage at the first node of the second transistor. The driving circuit includes a PMOS transistor coupling to the reference current source and the first transistor. The PMOS transistor is configured to: receive the comparison signal; and adjust a voltage at the first node of the first transistor to approach a voltage at the first node of the second transistor according to the comparison signal. The output current is equal to the reference current multiplied by a factor, and the factor is determined by a size ratio between the first transistor and the second transistor.

Yet another aspect of the present disclosure is directed to a driving circuit configured to provide an output current to drive a device. The driving circuit includes a reference current source configured to provide a reference current. The driving circuit includes a first transistor including a first node, a second node, and a third node. The driving circuit includes a second transistor including a first node of the second transistor, a second node of the second transistor coupling to the second node of the first transistor, and a third node of the second transistor. The driving circuit includes a voltage shifter coupled to the device and the second transistor. The driving circuit includes a comparator coupling to the first transistor and the second transistor, and configured to generate a comparison signal in response to a comparison of a voltage at the first node of the first transistor and a voltage at the first node of the second transistor. The driving circuit includes a voltage adjustment circuit coupling to the reference current source and the first transistor, and configured to: receive the comparison signal; and adjust a voltage at the first node of the first transistor to approach a voltage at the first node of the second transistor according to the comparison signal. The output current is equal to the reference current multiplied by a factor, and the factor is determined by a size ratio between the first transistor and the second transistor.

### BRIEF DESCRIPTION OF THE DRAWINGS

The foregoing aspects and many of the advantages of this application will become more readily appreciated as the same becomes better understood by reference to the following detailed description when taken in conjunction with the accompanying drawings:

FIG. 1A shows a circuit diagram of a driving circuit in accordance with one embodiment of the present disclosure.

FIG. 1B shows a circuit diagram of a driving circuit in accordance with another embodiment of the present disclosure.

FIG. 2 shows a current-voltage curve of a transistor in accordance with one embodiment of the present disclosure.

FIG. 3A shows a circuit diagram of a driving circuit in accordance with another embodiment of the present disclosure.

FIG. 3B shows a circuit diagram of a driving circuit in accordance with another embodiment of the present disclosure.

FIG. 4A shows a circuit diagram of a driving circuit in accordance with another embodiment of the present disclosure.

FIG. 4B shows an operation mode of a driving circuit in accordance with an embodiment of the present disclosure.

FIG. 4C shows another operation mode of a driving circuit in accordance with an embodiment of the present disclosure.

FIG. 5A shows an operation mode of a driving circuit in accordance with another embodiment of the present disclosure.

FIG. 5B shows another operation mode of a driving circuit in accordance with another embodiment of the present disclosure.

FIG. 6A shows a circuit diagram of a driving circuit in accordance with another embodiment of the present disclosure.

FIGS. 6B-6D show different configurations of a voltage adjustment circuit in accordance with different embodiments of the present disclosure.

FIGS. 7A-7C show different configurations of a voltage adjustment circuit in accordance with different embodiments of the present disclosure.

FIG. 8A shows a circuit diagram of a driving circuit in accordance with another embodiment of the present disclosure.

FIG. 8B shows a circuit diagram of a driving circuit in accordance with another embodiment of the present disclosure.

FIG. 9 shows a flow of an example method in accordance with embodiments of the present disclosure.

### DETAILED DESCRIPTION

The following embodiments accompany the drawings to illustrate the concept of the present disclosure. In the drawings or descriptions, similar or identical parts use the same reference numerals, and in the drawings, the shape, thickness, or height of the element can be reasonably expanded or reduced. The embodiments listed in the present application are only used to illustrate the present application and are not used to limit the scope of the present application. Any obvious modification or change made to the present application does not depart from the spirit and scope of the present application.

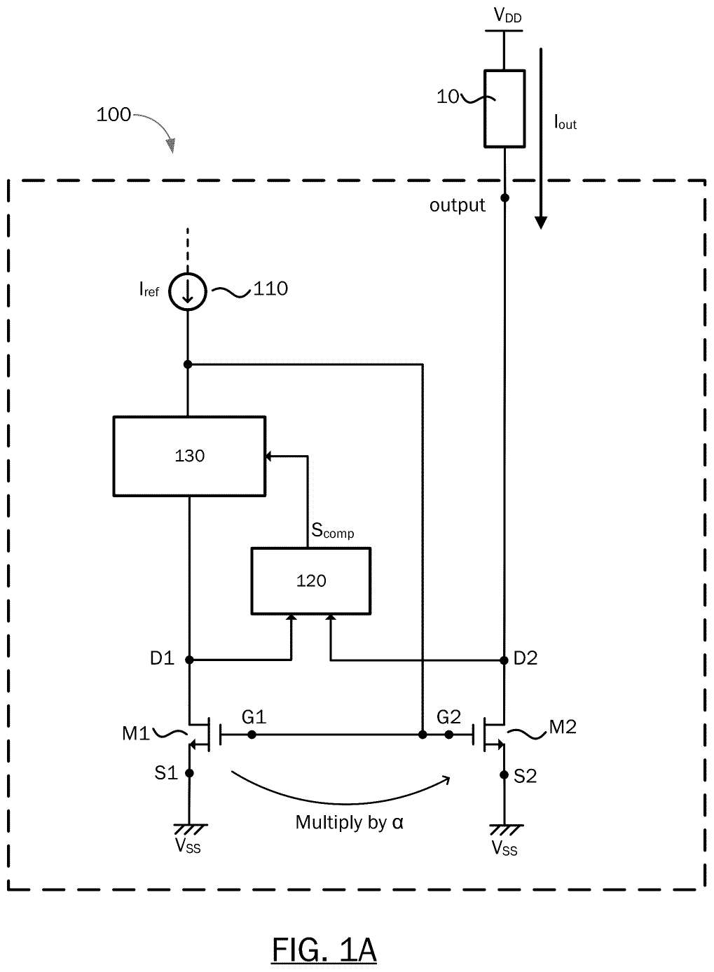

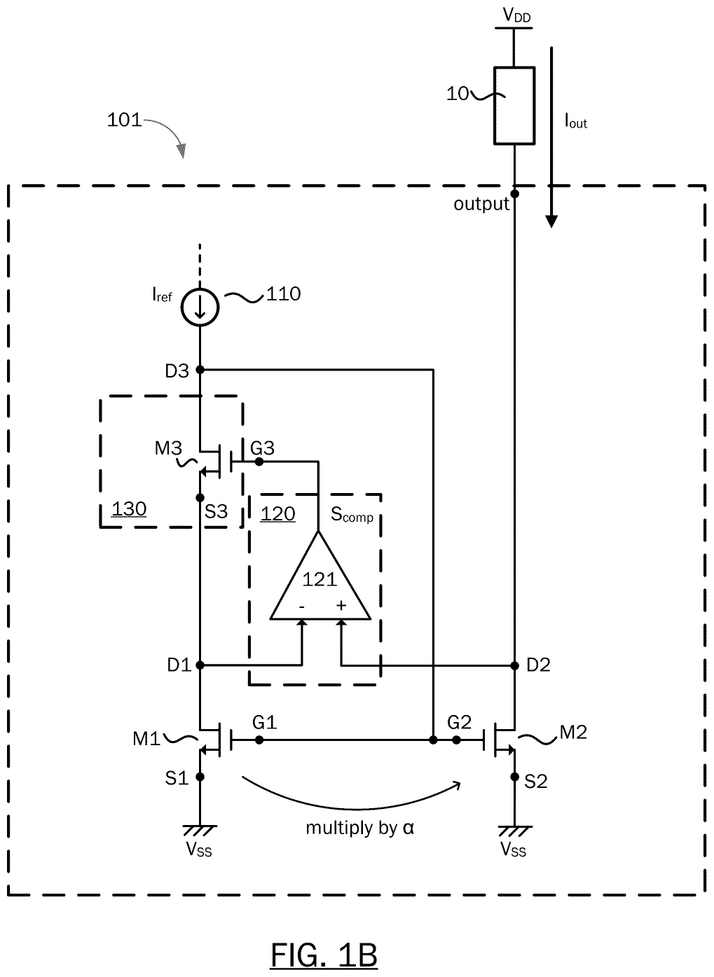

In analog circuits, current mirror circuits for reproducing an output current are standard. The accuracy of a current mirror is dominated by the similarity of the diode-connected MOS (e.g., M1 in FIG. 1A) to its replica MOS (e.g., M2 in FIG. 1A), where M1 and M2 share a same gate voltage. The drain terminal of M1 is receiving the reference current (I_{ref}), whereas the drain terminal of M2 is to output the output current (Iₒᵤₜ). The designed factor, α, is the expected mirror ratio between I_{ref} and Iₒᵤₜ. Typically, the difference between the V_{DS} (drain to source voltage) of M1 and M2 is to be minimized to guarantee the mirror accuracy between I_{ref} and Iₒᵤₜ. A common method to minimize the V_{DS} mismatch is introducing a voltage drop controller (or voltage drop buffer, for example, a cascode MOS) between the output node and the drain terminal of M2. During operations, the voltage drop controller accompanying a voltage sensor that senses the drain voltage of M1 reproduces a similar voltage to the drain of M2 (a typical example is the so-called “Cascode Current Mirror”). The main problem of this conventional V_{DS} mismatch reduction method is the voltage drop of the voltage drop controller itself introducing an inevitable voltage drop. Since the voltage headroom of output current path is often the most stringent path, the inevitable voltage-drop results in an obstacle to fulfill a low voltage circuit design. Accordingly, the driving circuitry that can be used in systems with low power supplies of the present disclosure solves these technical problems.

FIG. 1A shows a circuit diagram of a driving circuit in accordance with one embodiment of the present disclosure. The driving circuit 100 is configured to generate an output current Iₒᵤₜ as a driving current to device 10. The device 10 can be a light-emitting device, such as a laser diode, a light-emitting diode (LED), etc., electric elements, or electric circuits. The device 10 has a first terminal coupling to a power supply to receive a source voltage V_{DD}. The device 10 has a second terminal coupling to an output of the driving circuit 100 to receive the output current Iₒᵤₜ for activation, for example, emitting a light. The driving circuit 100 can be implemented by way of a current mirror. The current mirror circuits for reproducing output current to drive a device are commonly used in the current driving circuits. Based on the accuracy of these current mirror circuits, the device 10 that needs to be driven should operate within a suitable bias voltage range to ensure the accuracy of the output current (or driving current). Although the transistors M1 and M2 shown in FIG. 1A are NMOS, it is not to be a limitation. The transistors M1 and M2 can be replaced with other suitable transistors, such as PMOS, BJT, etc.

The driving circuit 100 includes a reference current source 110, a first transistor M1, a second transistor M2, a comparator 120, and a voltage adjustment circuit 130. The reference current source 110 is configured to provide the reference current I_{ref} as a reference for the driving circuit 100. The first transistor M1 electrically couples to the voltage adjustment circuit 130, and the voltage adjustment circuit 130 electrically couples to reference current source 110.

The driving circuit 100 can be regarded as a current mirror. The first transistor M1, the voltage adjustment circuit 130, and the reference current source 110 are positioned on a first current path of the current mirror. The second transistor M2 is positioned on a second current path of the current mirror. The reference current I_{ref} generated by the reference current source 110 can flow through the first current path, and an output current (or the driving current) Iₒᵤₜ can flow through the second current path. The output current Iₒᵤₜ is approximately equal to the reference current I_{ref} multiplied by a factor (gain) determined by the size ratio between the first transistor M1 and the second transistor M2. The reference current I_{ref} can be a precise reference current, and more particularly, can be generated according to an off-chip resistor and/or build-in band-gap device.

The first transistor M1 has a first node D1 (e.g., drain) of the first transistor M1, a second node G1 (e.g., gate) of the first transistor M1, and a third node S1 (e.g., source) of the first transistor M1. The second transistor M2 has a first node D2 (e.g., drain) of the second transistor M2, a second node G2 (e.g., gate) of the second transistor M2, and a third node S2 (e.g., source) of the second transistor M2. The first node D2 of the second transistor M2 is the output of the driving circuit 100 and electrically couples to the device 10 for providing the output current Iₒᵤₜ to drive the device 10. The accuracy of the current mirror is dominated by the similarity of the first transistor M1 to the second transistor M2. The second node G1 of the first transistor M1 couples to the second node G2 of the second transistor M2 to share the same voltage (e.g., V_{G1}=V_{G2}). The second node G1 of the first transistor M1 and the second node G2 of the second transistor M2 also couple to the input terminal of the voltage adjustment circuit 130 (or the output terminal of the reference current source 110), so that the voltages V_{G1} at the node G1, and V_{G2} at the node G2 are consistent with the input terminal of the voltage adjustment circuit 130 (or the output terminal of the reference current source 110). The first node D1 of the first transistor M1 receives the reference current I_{ref}, whereas the first node D2 of the second transistor M2 outputs the output current Iₒᵤₜ which is approximately equal to the reference current I_{ref} multiplied by a factor α. The third node S1 of the first transistor M1 and the third node S2 of the second transistor M2 electrically couple to a common voltage V_{SS} (e.g., the ground). A factor α is the expected mirror ratio, which is a ratio of the output current Iₒᵤₜ to the reference current I_{ref} and can be adjusted by varying the size ratio of the width (W) and length (L) of the second transistor M2 and the first transistor M1. The difference of the voltage difference (e.g., V_{DS1}) between the first node D1 and the third node S1 of the first transistor M1 and the voltage difference (e.g., V_{DS2}) between the first node D2 and the third node S2 of the second transistor M2 should be minimized to guarantee the mirror accuracy between I_{ref} and Iₒᵤₜ.

For example, the voltage difference between the second node G1 and the third node S1 of the first transistor M1 is V_{GS1}, and the voltage difference between the second node G2 and the third node S2 of the second transistor M2 is V_{GS2}. Since V_{G1}=V_{G2}, V_{GS1}=V_{GS2}. The voltage difference between the first node D1 and the third node S1 of the first transistor M1 is V_{DS1}, and the voltage difference between the first node D2 and the third node S2 of the second transistor M2 is V_{DS2}. If the voltage V_{D1} at the first node D1 of the first transistor M1 is approximately equal to the voltage V_{D2} at the first node D2 of the second transistor M2, V_{DS1}≈V_{DS2}. Then,

$$( \frac{{W}_{M 1}}{{L}_{M 1}} ) \times α = ( \frac{{W}_{M 2}}{{L}_{M 2}} ) .$$

$${I}_{out} \approx α \times {I}_{ref}$$

The comparator 120 has two inputs coupling to the first node D1 of the first transistor M1 and the first node D2 of the second transistor M2 respectively, and an output coupling to the voltage adjustment circuit 130. The comparator 120 is configured to compare a voltage V_{D2} on the first node D2 of the second transistor M2 and a voltage V_{D1} on the first node D1 of the second transistor M1 and generate a comparison signal S_{comp}, which is related to the difference between the voltages V_{D2} and V_{D1}. The comparator 120 provides the comparison signal S_{comp} to the voltage adjustment circuit 130, and the voltage adjustment circuit 130 is configured to adjust the voltage V_{D1} at the first node D1 of the first transistor M1 to be approximately equal to the voltage V_{D2} at the first node D2 of the second transistor M2 according to the comparison signal S_{comp}. As the result, the output current Iₒᵤₜ flowing through the first node D2 of the second transistor M2 and the reference current I_{ref} can comply with the aforementioned mathematical relationship, thereby the driving circuit 100 can generate a stable and accurate output current Iₒᵤₜ to drive the device 10.

FIG. 1B shows a circuit diagram of a driving circuit in accordance with another embodiment of the present disclosure. The driving circuit 101 includes an amplifier 121 for the comparator 120 and a third transistor M3 for the voltage adjustment circuit 130. The amplifier 121 is configured to output a comparison signal S_{comp} in response to a comparison of the voltage V_{D1} at the node D1 and the voltage V_{D2} at the node D2. The third transistor M3 is configured to adjust the voltage V_{D1} at the first node D1 of the first transistor M1 to be approximately equal to the voltage V_{D2} at the first node D2 of the second transistor M2 according to the comparison signal S_{comp}. The comparison signal S_{comp} can be obtained by multiplying the voltage difference between V_{D1} and V_{D2} by a gain. The third transistor M3 has a first node D3 (e.g., drain) coupling to the reference current source 110 and coupling to the second nodes G1, G2 of the transistors M1 and M2, a second node G3 (e.g., gate) coupling to the amplifier 121 to receive the comparison signal S_{comp}, and a third node S3 (e.g., source) coupling to the first node D1 of the first transistor M1. The current flowing through the third transistor M3 is maintained to be the reference current I_{ref}, so the voltage difference V_{DS3} between the first node D3 and the third node S3 of the third transistor M3 may vary according to the comparison signal S_{comp}. Hence, the voltages V_{G1}, V_{G2} of the second nodes G1, G2 of the first transistor M1 and the second transistor M2 can be adjusted based on the comparison signal S_{comp} received by the second node G3 of the third transistor M3. The voltage V_{S3} of the third node S3 of the third transistor M3 also can be adjusted based on the comparison signal S_{comp} received by the second node G3 of the third transistor M3, so that the voltage V_{D1} of the first node D1 of the first transistor M1 can be adjusted to approach the voltage V_{D2} of the first node D2 of the second transistor M2.

When the voltage V_{D2} is larger than the voltage V_{D1}, (V_{D2}−V_{D1})>0, the comparison signal S_{comp} generated by the amplifier 121 forces the voltage V_{G3} of the second node G3 of the third transistor M3 to increase. Since the current flowing through the third transistor M3 and the first transistor M1 on the first current path is maintained as the reference current I_{ref}, the voltage V_{D3} of the first node D3 of the third transistor M3 will decrease, thereby causing the voltage V_{G1} of the second node G1 of the first transistor M1 to decrease. The voltage V_{D1} of the first node D1 of the first transistor M1 will increase to approach the voltage V_{D2} of the first node D2 of the second transistor M2 to keep the output current Iₒᵤₜ approximately equal to the reference current I_{ref} multiplied by a factor.

When the voltage V_{D2} is less than the voltage V_{D1}, that is (V_{D2}−V_{D1})<0, the comparison signal S_{comp} generated by the amplifier 121 forces the voltage V_{G3} of the second node G3 of the third transistor M3 to decrease. Since the current flowing through the third transistor M3 and the first transistor M1 on the first current path is maintained as the reference current I_{ref}, the voltage V_{D3} of the first node D3 of the third transistor M3 will increase, thereby causing the voltage V_{G1} of the second node G1 of the first transistor M1 to increase. The voltage V_{D1} of the first node D1 of the first transistor M1 will decrease to approach the voltage V_{D2} of the first node D2 of the second transistor M2 to keep the output current Iₒᵤₜ approximately equal to the reference current I_{ref} multiplied by a factor.

The adjustment mechanisms mentioned above continue to operate until the voltage V_{D1} of the first node D1 of the first transistor M1 is approximately equal to the voltage V_{D2} of the first node D2 of the second transistor M2 so that the voltage difference V_{DS1} of the first node D1 and the third node S1 of the first transistor M1 is approximately equal to the voltage difference V_{DS2} of the first node D2 and the third node S2 of the second transistor M2. Therefore, in an example, Iₒᵤₜ≈α×I_{ref} can be assured, where α is the factor mentioned earlier. Since there is no series component (e.g., transistor) which results in an inevitable voltage drop, the first node D2 of the second transistor M2 can withstand a low voltage Vₒᵤₜ at the output of the driving circuit 101. Hence, the driving circuit 101 can be flexibly applied to systems with low power supply or coupled to devices with high impedance to provide a stable and accurate current.

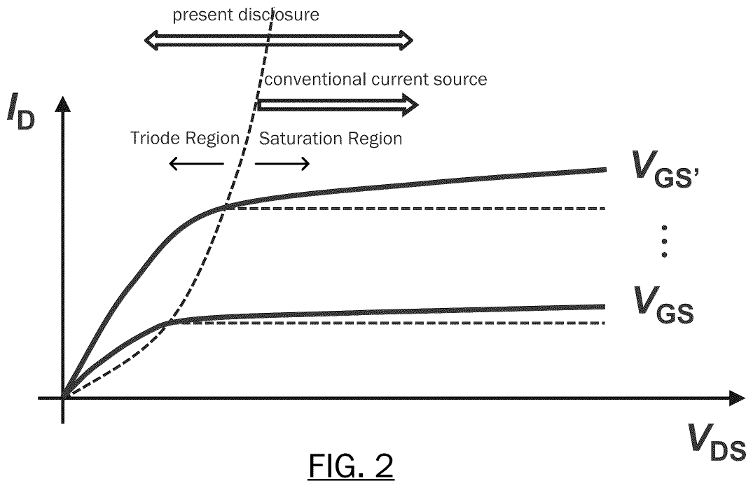

FIG. 2 shows a current-voltage curve of a transistor in accordance with one embodiment of the present disclosure. The current-voltage (I-V) curve can be the I-V characteristic of the first transistor M1, the second transistor M2, and/or the third transistor M3. For example, FIG. 2 shows several curves of the drain current (I_{D}) versus the drain-to-source voltage (V_{DS}) curve for different gate-to-source voltage (V_{GS}) of an NMOS. Each curve has at least two regions for operation, which are the saturation region and the triode region. In the triode region, the transistor operates like a resistor as the current I_{D} varies approximately linearly with the voltage V_{DS}. In the saturation region, the current I_{D} does not change significantly even if the voltage V_{DS} changes. Therefore, when a transistor is applied to a current source or current mirror, a specific Vas can be given or fixed and the transistor may operate in the saturation region, then it can provide a substantially constant current I_{D} to a device that is coupled to the drain terminal of the transistor. However, as the voltage Vos is a given value and the transistor needs to be operated in the saturation region, the allowable variation in the voltage V_{DS} that the transistor can tolerate is limited. In other words, when a device is coupled to the drain terminal of the transistor to receive a substantially constant driving current, the voltage difference generated by it is limited to a small range, such that changes in the voltage V_{D} or voltage V_{DS} of the transistor can still keep the transistor operating in the saturation region.

Referring to FIGS. 1A-1B, the voltages V_{G1} and V_{G2} at the second nodes G1, G2 of the first transistor M1 and the second transistor M2 can be dynamically changed through the comparator 120 and the voltage adjustment circuit 130, and the voltage difference V_{DS1} of the first node D1 and the third node S1 of the first transistor will also change accordingly. Hence, as shown in FIG. 2, the operation regions of the first transistor M1 and the second transistor M2 can extend to cover the triode region and the saturation region for sustaining the output current. In detail, for example, in the driving circuit 100 or 101, the allowable voltage variation range of the first nodes D1, D2 of the first transistor M1 and the second transistor M2 is larger due to the operation region covering the triode region and the saturation region. As such, the driving circuit 100 or 101 can provide a substantially constant driving current even when the driving circuit 100 or 101 couples to a device 10 that generates a high voltage difference or has a high impedance. In addition, even if the device 10 couples to a power supply with a low source voltage V_{DD}, which results in a lower voltage Vₒᵤₜ at the output terminal of the driving circuit 100 or 101 (i.e, the first node D2 of the second transistor M2), the driving circuit 100 or 101 still can provide a substantially constant and accurate driving current. Therefore, the design of the devices or other circuits driven by the driving circuit 100 or 101 can be more flexible.

The aforementioned driving circuit has greater flexibility to couple different devices or circuits that need to be driven. For instance, in order for the comparator 120 and the voltage adjustment circuit 130 can operate the current adjustment mechanism accurately, the voltage V_{G1} at the second node G1 of the first transistor M1 can be higher than the voltage V_{D1} at the first node D1 of the first transistor M1 by a sufficient value. As shown in FIGS. 1A-1B, if the impedance of the device 10 is small or the source voltage V_{DD} provided by a power supply is high, the voltage Vₒᵤₜ at the output of the driving circuit 100 (or 101) or the voltage V_{D2} at the first node D2 of the second transistor M2 may be too high, resulting in the voltages V_{G1}, V_{G2} at the second nodes G1, G2 of the first transistor M1 and the second transistor M2 to be too small. Then, the comparator 120 and the voltage adjustment circuit 130 may not operate properly and cannot accurately adjust the output current Iₒᵤₜ.

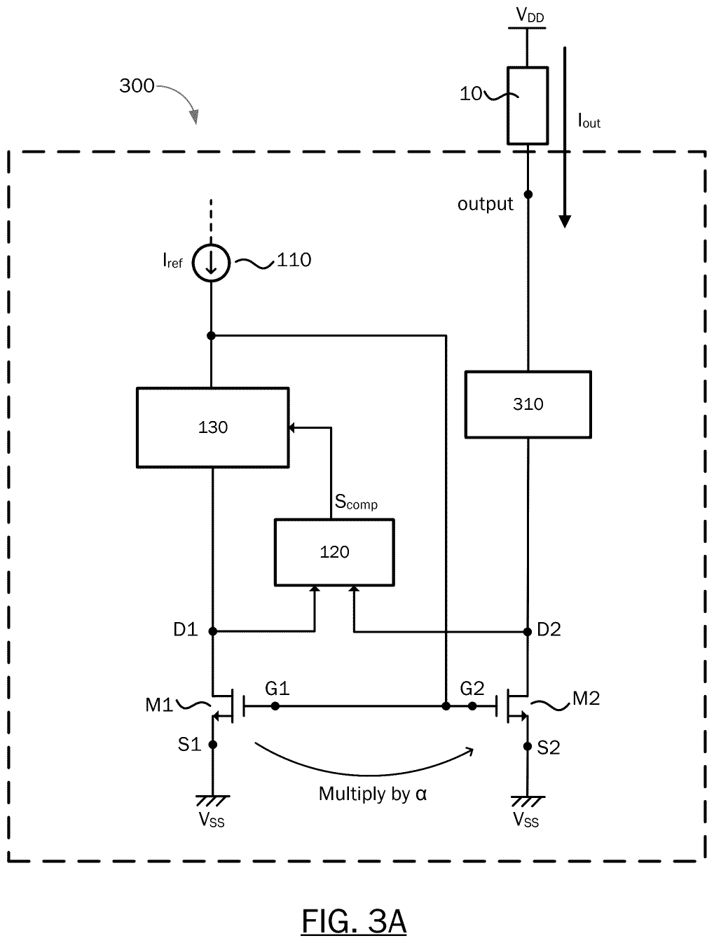

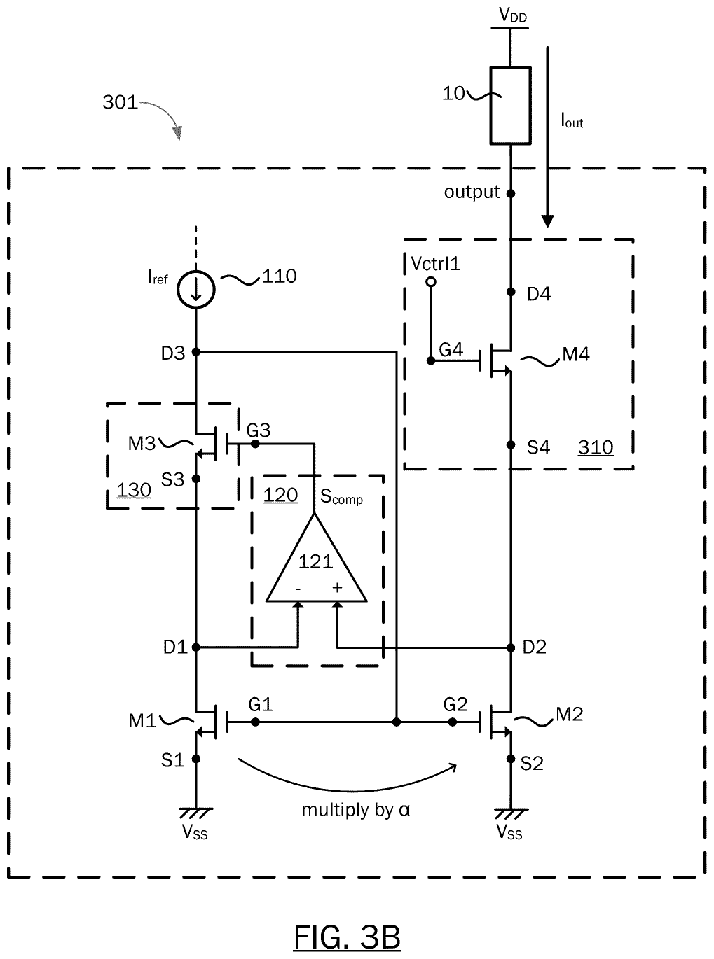

FIG. 3A shows a circuit diagram of a driving circuit in accordance with another embodiment of the present disclosure. Compared to the driving circuit 100 or 101, the driving circuit 300 additionally can include a voltage shifter 310 located between the first node D2 of the second transistor M2 and the output of the driving circuit 300. The voltage shifter 310 can be configured to adjust the voltage V_{D2} at the first node D2 of the second transistor M2 by shifting the voltage Vₒᵤₜ at the output of the driving circuit 300 to prevent the voltage V_{D2} at the first node of the second transistor M2 from becoming too high and causing the current adjustment mechanism of the driving circuit to fail.

FIG. 3B shows a circuit diagram of a driving circuit in accordance with another embodiment of the present disclosure. The voltage shifter 310 of the driving circuit 301 can include a fourth transistor M4. The fourth transistor M4 can include a first node D4, a second node G4, and a third node S4. The first node D4 couples to the output of the driving circuit 301 and couples to the device 10. The third node S4 couples to the first node D2 of the second transistor M2. A first control signal Vctrl1 can be applied to the second node G4 of the fourth transistor M4 to control the voltage difference V_{DS4} between the first node D4 and the third node S4 of the fourth transistor M4. So, the fourth transistor M4 can adjust the voltage V_{D2} at the first node D2 of the second transistor M2 by performing a voltage shift on the voltage Vₒᵤₜ at the output of the driving circuit based on V_{DS4}. The first control signal Vctrl1 can be controlled by analog or digital methods (e.g., certain continuous tuning ranges or discrete tuning steps).

In an embodiment, the fourth transistor M4 can also be configured as a switch to control connection and disconnection between the second transistor M2 and the device 10. When the device 10 couples to the second transistor M2 through the fourth transistor M4 based on the first control signal Vctrl1, the configuration of the driving circuit 301 can be the same as the driving circuit 101 shown in FIG. 1B. For example, if the device 10 is a laser diode, and a system with the laser diode does not need to emit laser light, the fourth transistor M4 can be configured to disconnect the laser diode from the driving circuit 301 in order to ensure eye safety and/or saving power.

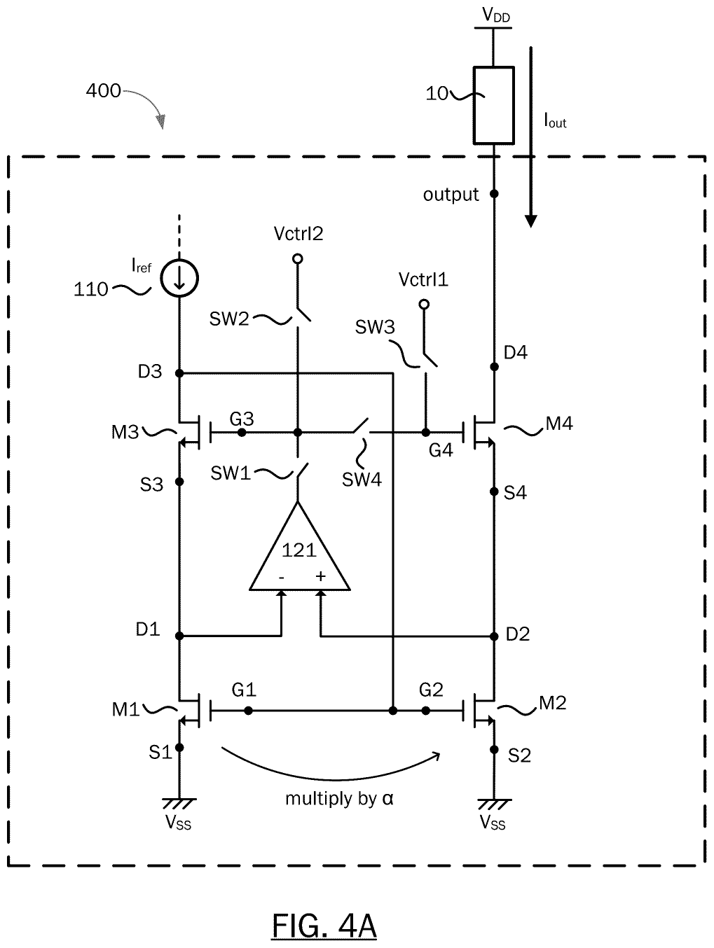

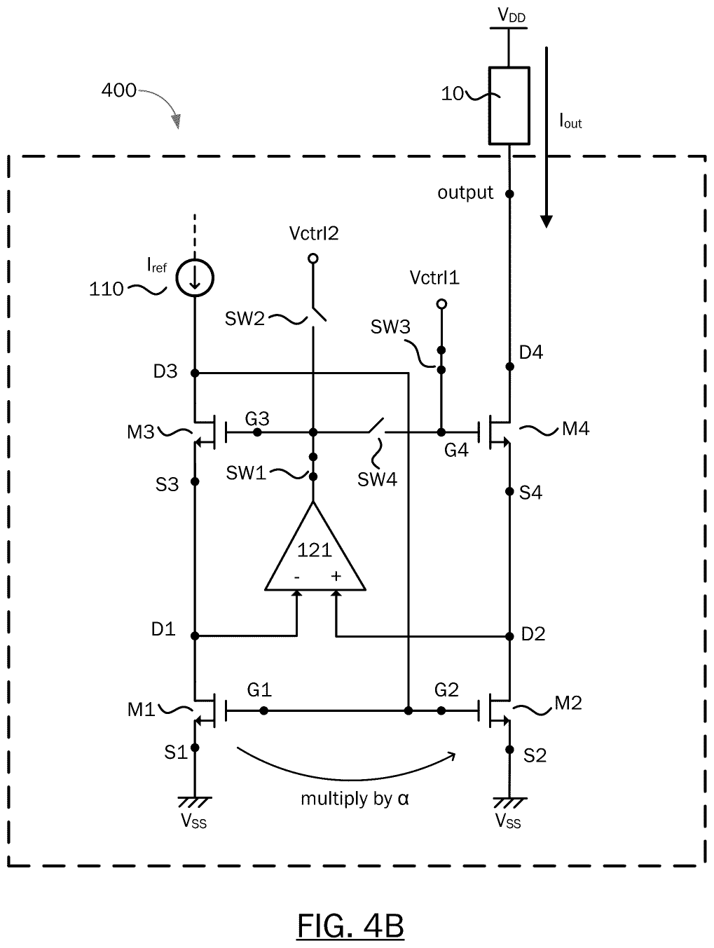

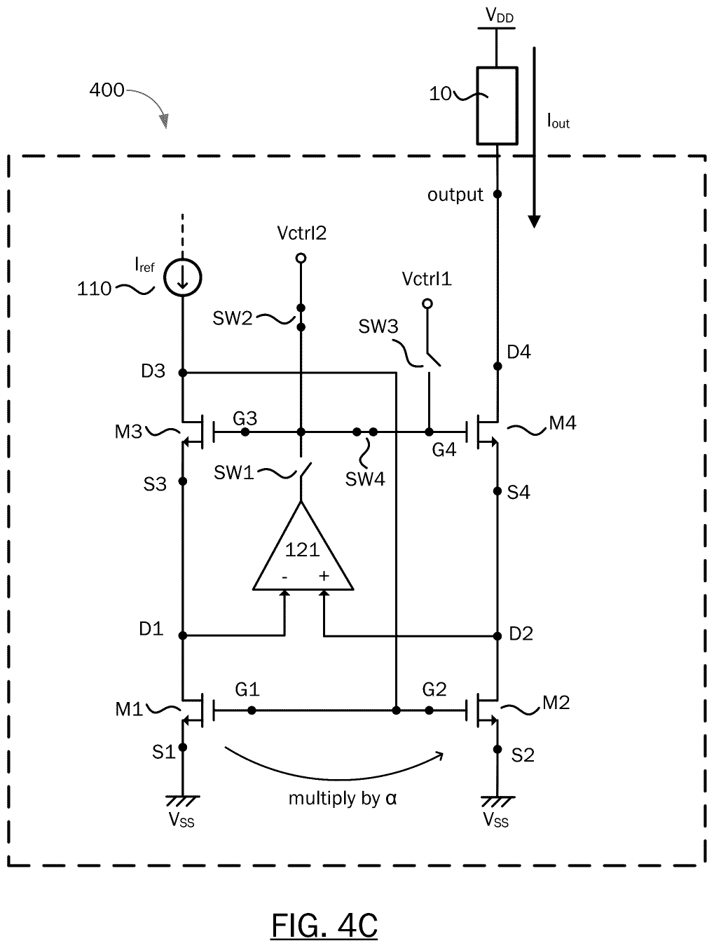

FIG. 4A shows an example circuit diagram of a driving circuit in accordance with another embodiment of the present disclosure. In the example, compared to the driving circuit 301, the driving circuit 400 additionally includes a first switch SW1 coupling to the amplifier 121 and the second node G3 of the third transistor M3, a second switch SW2 coupling to a second control signal Vctrl2 and the second node G3 of the third transistor M3, a third switch SW3 coupling to the first control signal Vctrl1 and the second node G4 of the fourth transistor M4, and a fourth switch SW4 coupling to the second node G3 of the third transistor M3 and the second node G4 of the fourth transistor M4. In order to be applied to different driven devices or driven circuits, the driving circuit 400 may have at least two modes to provide substantially constant and accurate output current Iₒᵤₜ through the control of multiple switches.

FIG. 4B shows an example operation mode of a driving circuit in accordance with an embodiment of the present disclosure. In the example, when the driving circuit 400 operates in the first operation mode, the amplifier 121 couples to the second node G3 of the third transistor M3 through the first switch SW1, and the second node G4 of the fourth transistor M4 couples to the first control signal Vctrl1 through the third switch SW3. In addition, the second control signal Vctrl2 disconnects from the second node G3 of the third transistor M3 through the second switch SW2, and the second node G3 of the third transistor M3 disconnects from the second node G4 of the fourth transistor M4 through the fourth switch SW4. The architecture of the first operation mode is the same as the aforementioned FIGS. 3A-3B, and is suitable for driving high-impedance devices or applied in a system with low power supply voltage.

FIG. 4C shows another example operation mode of a driving circuit in accordance with an embodiment of the present disclosure. In the example, when the driving circuit 400 operates in the second operation mode, the second control signal Vctrl2 couples to the second node of the third transistor M3 through the second switch SW2, and the second node of the third transistor M3 couples to the second node G4 of the fourth transistor M4 through the second switch SW2 and the fourth switch SW4. In addition, the amplifier 121 disconnects from the second node G3 of the third transistor M3 through the first switch SW1, and the second node G4 of the fourth transistor M4 disconnects from the first control signal Vctrl1 through the second switch SW2. Then, the second operation mode is a current mirror. The voltages of the second nodes G1, G2 of the first transistor M1 and the second transistor M2 cannot be dynamically adjusted, so the first transistor M1 and the second transistor M2 must operate in the saturation region to sustain the output current Iₒᵤₜ. The third transistor M3 is configured to sustain a voltage difference across V_{D3} and V_{D1}. While keeping the fourth transistor M4 operating in the saturation region or near the saturation region, the fourth transistor M4 can reduce the change of V_{D2} caused by V_{D4} variation. By guaranteeing the third transistor M3 also operating in the saturation region and properly choosing the size ratio of the width and length between the third transistor M3 and the fourth transistor M4, the similarity of V_{D1} and V_{D2} can be assured. Since the difference between V_{DS1} and V_{DS2} can be significantly reduced due to the similar V_{D1} and V_{D2}, the second transistor M2 can generate an accurate output current Iₒᵤₜ that approximately equal to the reference current I_{ref} multiplied by a factor on the second current path. Since the fourth transistor M4 results in an inevitable voltage drop at the first node D2 of the second transistor M2, the second operation mode is more suitable for a system with high (or normal) power supply voltage. The second control signal Vctrl2 can be controlled by analog or digital methods (e.g., certain continuous tuning ranges or discrete tuning steps).

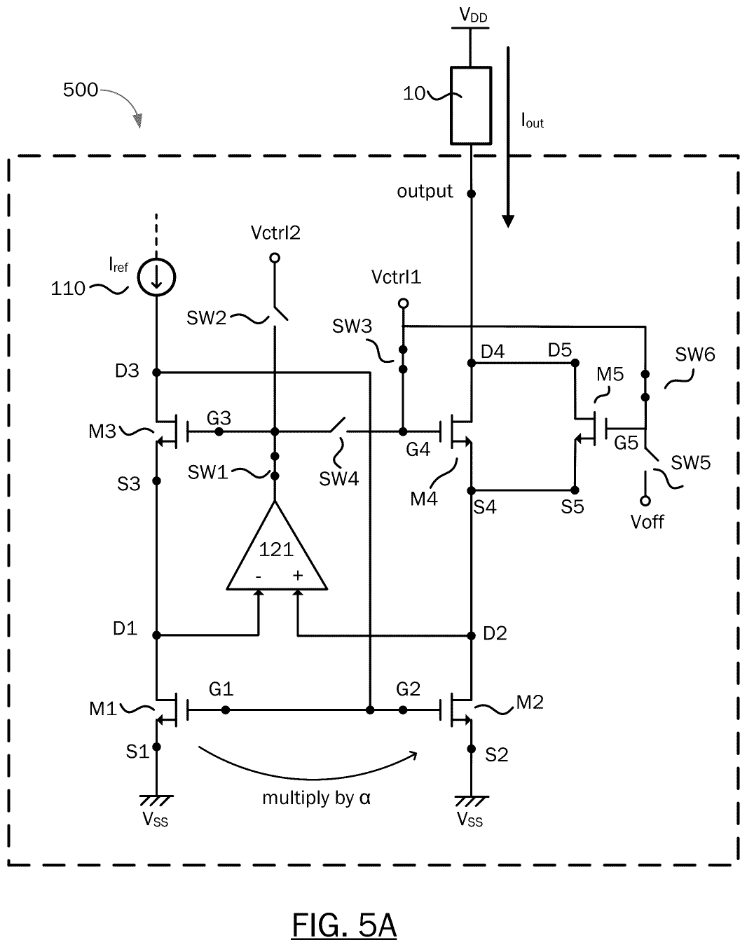

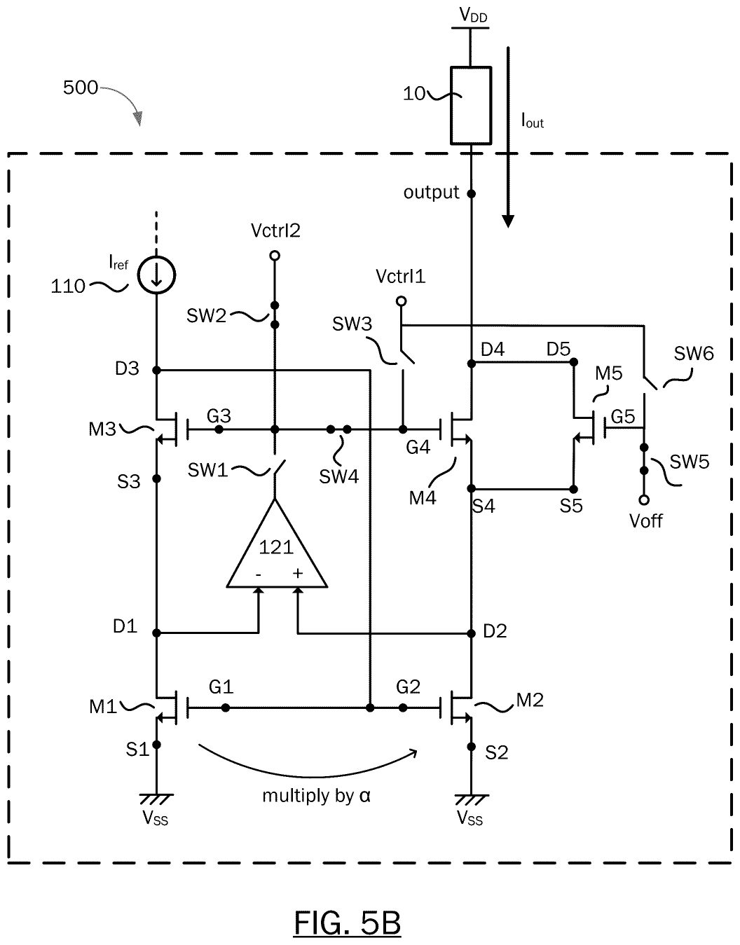

FIG. 5A shows an example operation mode of a driving circuit in accordance with another embodiment of the present disclosure. Compared to the driving circuit 400 shown in FIG. 4B, the driving circuit 500 additionally includes a fifth transistor M5 coupling to the fourth transistor M4 to decrease the voltage drop induced by the fourth transistor M4, a fifth switch SW5, and a sixth switch SW6. The fifth switch SW5 couples to a control signal V_{off} and the second node G5 of the fifth transistor M5. It is configured to turn off the fifth transistor M5 by the control signal V_{off}. The sixth switch SW6 is configured to control the connection and disconnection between the second node G5 of the fifth transistor M5 and the first control signal Vctrl1. The fifth transistor M5 and the fourth transistor M4 collectively form a switch configured to control connection and disconnection between the second transistor M2 and the device 10. The fifth transistor M5 has a first node D5 coupling to the first node D4 of the fourth transistor M4, a second node G5 coupling to the first control signal Vctrl1 through the sixth switch SW6, and a third node S5 coupling to the third node S4 of the fourth transistor M4. The second node G5 disconnects from the control signal V_{off} through the fifth switch SW5.

FIG. 5B shows an example operation mode of a driving circuit in accordance with another embodiment of the present disclosure. The driving circuit 500 can also be switched to the operation mode as shown in FIG. 4C. The second node G5 of the fifth transistor M5 couples to the control signal V_{off} through the fifth switch SW5 to turn off the fifth transistor M5, and the second node G5 of the fifth transistor M5 disconnects from the first control signal Vctrl1 and the second node G4 of the fourth transistor M4 through the sixth switch SW6. Then, the configuration of the driving circuit 500 shown in FIG. 5B is the same as the driving circuit 400 shown in FIG. 4C. In another embodiment, the size ratio of width and length of the fourth transistor M4 and the third transistor M3 can be the same as that of the second transistor M2 and the first transistor M1 for better matching of the first current path and the second current path.

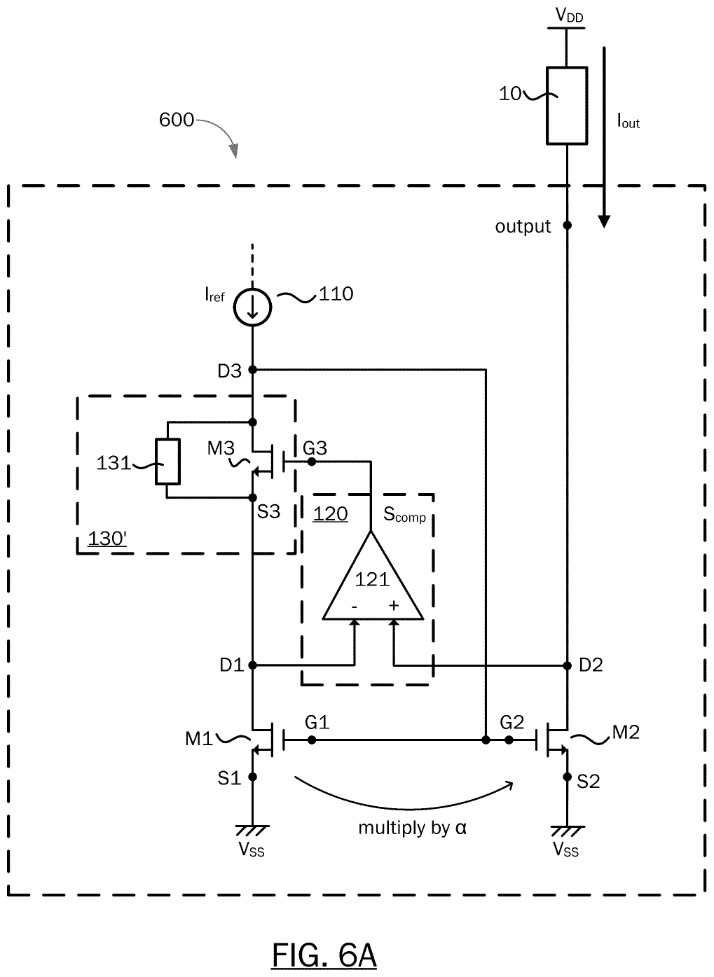

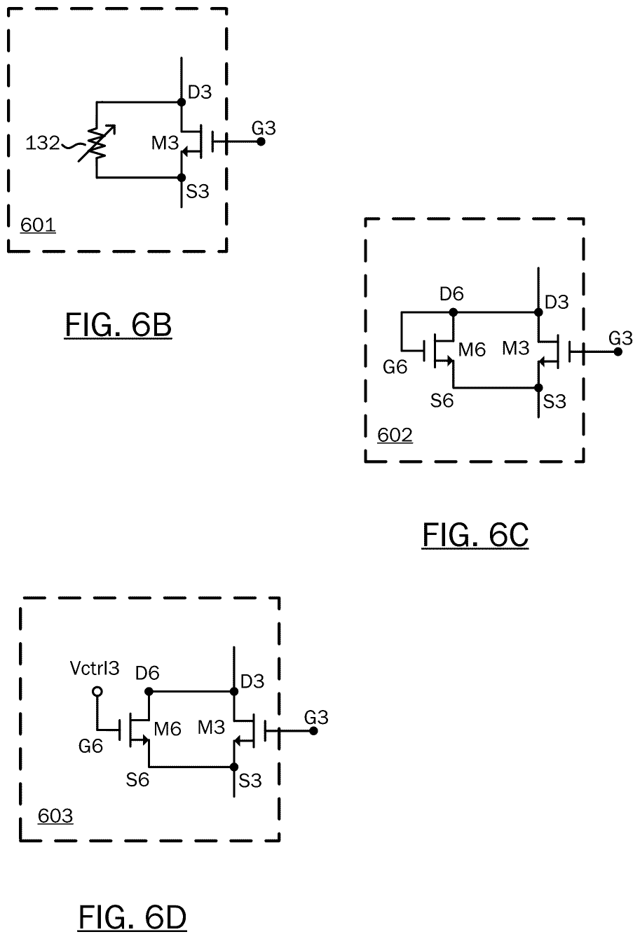

FIG. 6A shows an example circuit diagram of a driving circuit in accordance with another embodiment of the present disclosure. Compared to the driving circuit 101, the voltage adjustment circuit 130′ of the driving circuit 600 additionally includes a conductive device 131 coupling to the third transistor M3. The conductive device 131 couples to the third transistor M3 in parallel to limit the gain of a control loop formed by the first transistor M1, the second transistor M2, the comparator 120, and the third transistor M3, such that the control loop will be more stable and stay in the desired region. FIGS. 6B-6D show different configurations of a voltage adjustment circuit in accordance with different embodiments of the present disclosure. As shown in FIG. 6B, the conductive device of the voltage adjustment circuit 601 can be implemented by a resistor 132 coupling to the third transistor M3 in parallel. In an embodiment, the resistor 132 can be a variable resistor controlled by analog or digital method. The resistor 132 has a first terminal coupling to the first node D3 of the third transistor M3 and a second terminal coupling to the third node S3 of the third transistor M3. As shown in FIG. 6C, the conductive device of the voltage adjustment circuit 602 can be implemented by a sixth transistor M6 coupling to the third transistor M3 in parallel. The sixth transistor M6 has a first node D6 coupling to the first node D3 of the third transistor M3, a second node G6 coupling to the first node D3 of the third transistor M3 and the first node D6 of the sixth transistor M6, and a third node S6 coupling to the third node S3 of the third transistor M3. As shown in FIG. 6D, the conductive device of the voltage adjustment circuit 603 can be implemented by a sixth transistor M6 coupling to the third transistor M3 in parallel. The sixth transistor M6 has a first node D6 coupling to the first node D3 of the third transistor M3, a third node S6 coupling to the third node S3 of the third transistor M3. A third control signal Vctrl3 is applied to a second node G6 of the sixth transistor M6 to adjust the gain of the control loop. The third control signal Vctrl3 can be controlled by analog or digital methods (e.g., certain continuous tuning ranges or discrete tuning steps).

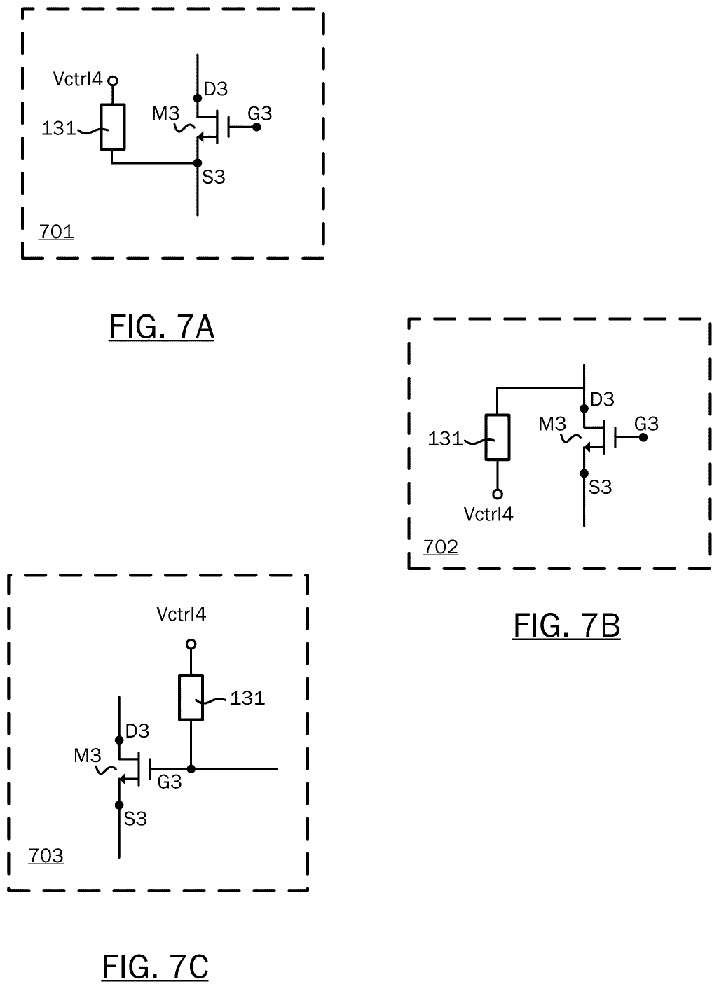

Referring to FIG. 6A, to limit the gain of the control loop formed by the first transistor M1, the second transistor M2, the comparator 120, and the third transistor M3, to be more stable and stay in the desired region, a control signal can be applied to one of the nodes of the third transistor M3 through a conductive device. FIGS. 7A-7C show different configurations of a voltage adjustment circuit in accordance with different embodiments of the present disclosure.

As shown in FIG. 7A, compared to the voltage adjustment circuit 130′ of the driving circuit 600, the voltage adjustment circuit 701 includes a conductive device 131 coupling to the third node S3 of the third transistor M3. A fourth control signal Vctrl4 can apply to the third node S3 of the third transistor M3 through the conductive device 131.

As shown in FIG. 7B, compared to the voltage adjustment circuit 130′ of the driving circuit 600, the voltage adjustment circuit 702 includes a conductive device 131 coupling to the first node D3 of the third transistor M3. A fourth control signal Vctrl4 can apply to the first node D3 of the third transistor M3 through the conductive device 131.

As shown in FIG. 7C, compared to the voltage adjustment circuit 130′ of the driving circuit 600, the voltage adjustment circuit 703 includes a conductive device 131 coupling to the second node G3 of the third transistor M3. A fourth control signal Vctrl4 can apply to the second node G3 of the third transistor M3 through the conductive device 131. The fourth control signal Vctrl4 can be controlled by analog or digital methods (e.g., certain continuous tuning ranges or discrete tuning steps).

The transistors mentioned earlier in the disclosure embodiments use NMOS transistor as an example in the drawings. It is to be understood that the type of the transistors is not limited thereto. For example, the transistor M3 shown in the aforementioned drawings can be a PMOS transistor.

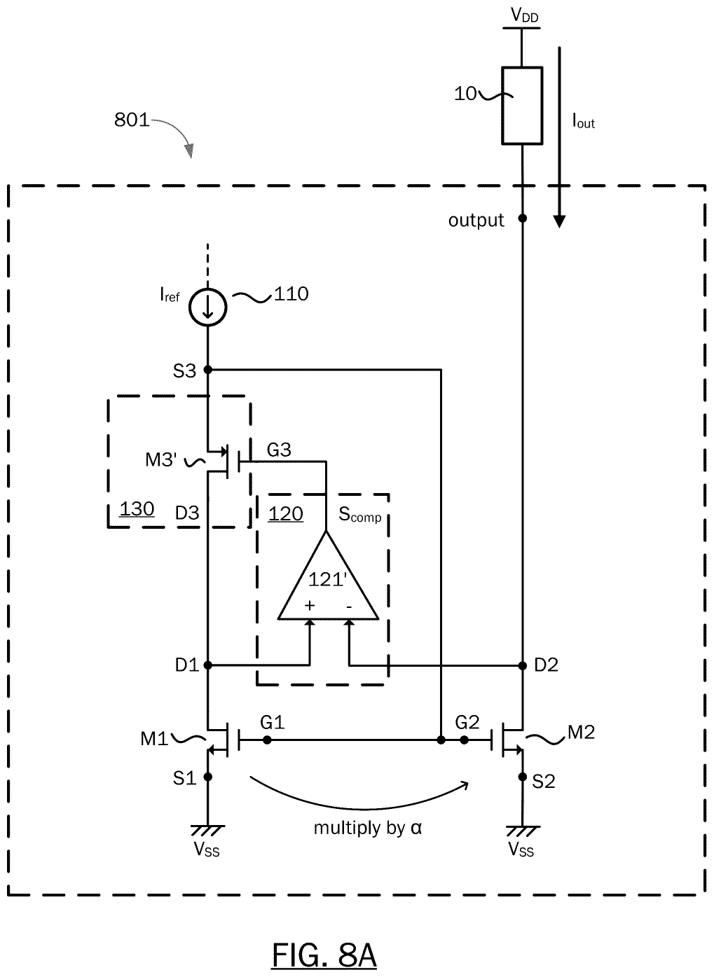

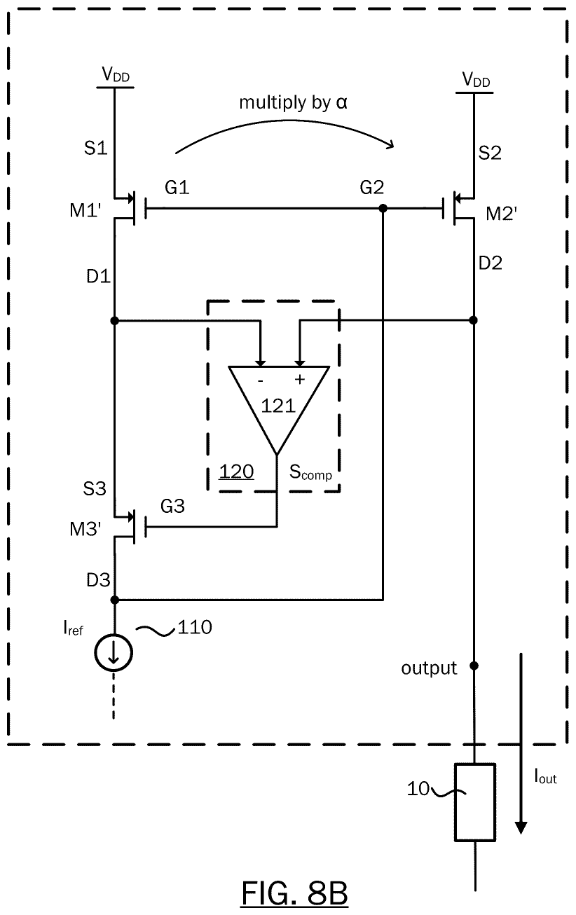

FIG. 8A shows a circuit diagram of an example driving circuit in accordance with another embodiment of the present disclosure. Compared to the driving circuit 101, the voltage adjustment circuit 130 of the driving circuit 801 can be implemented by a third transistor M3′ and the comparator 120 can be implemented by an amplifier 121′. The third transistor M3′ can be a PMOS transistor, and the inputs of the amplifier 121′ can have the opposite polarity to that of the amplifier 121 in FIG. 1B. By replacing NMOS transistor M3 with PMOS transistor M3′, the overall noise in the driving circuit can be reduced, due to the lower flicker noise performance of PMOS. Further noise reduction can be performed by replacing all the NMOS transistors in FIG. 1B with PMOS, only the direction of the output current is inversed. FIG. 8B shows a circuit diagram of an example driving circuit in accordance with another embodiment of the present disclosure. Compared to the driving circuit 101, the first transistor M1′, the second transistor M2′, and the third transistor M3′ can be PMOS transistors.

The transistors mentioned in the disclosure embodiments use MOSFET as an example in the drawings. The rest pins (pins other than drain, gate, and source) are not explicitly shown in the drawings, due to the other pins can be connected to arbitrary points that sustain a transistor behavior and do not cause reliability issue or unintentional current leakage.

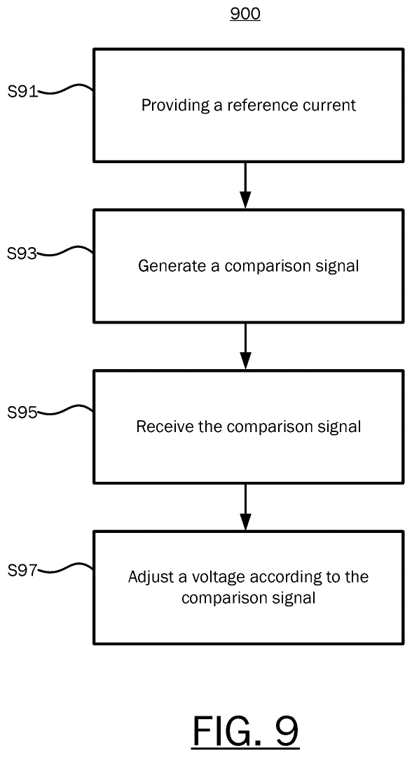

FIG. 9 shows a flow of an example method 900 with an embodiment of the present disclosure. The example method 900 can be performed by a controller configured to perform the operations of method 900. The controller can be or include, for example, a driving circuit.

At S91, the controller can provide a reference current. For instance, the controller can include a reference current source configured to provide a reference current.

At S93, the controller can generate a comparison signal. For instance, the controller can include a first transistor. The first transistor can include a first node, a second node, and a third node. The controller can include a second transistor with respective nodes. The second transistor can include a first node, a second node coupling to the second node of the first transistor, and a third node. The controller can include a comparator coupled to the first transistor and the second transistor. The comparator can be configured to generate the comparison signal in response to a comparison of a voltage at the first node of the first transistor and a voltage at the first node of the second transistor, as described herein.

At S95, the controller can receive the comparison signal. For instance, the controller can include a voltage adjustment circuit (e.g., a PMOS transistor) coupled to the reference current source and the first transistor, and including a third transistor and a conductive device coupling to the third transistor. The voltage adjustment circuit can be configured to receive the comparison signal (e.g., from the comparator or an intermediate component).

At S97, the controller can adjust a voltage according to the comparison signal. For instance, the voltage adjustment circuit can adjust a voltage at the first node of the first transistor to approach a voltage at the first node of the second transistor according to the comparison signal. The output current can be equal to the reference current multiplied by a factor. As described herein, the factor can be determined by a size ratio between the first transistor and the second transistor.

While the disclosure has been described by way of example and in terms of a preferred embodiment, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A driving circuit configured to provide an output current to drive a device, comprising:
a reference current source configured to provide a reference current;
a first transistor comprising a first node, a second node, and a third node;
a second transistor comprising a first node of the second transistor, a second node of the second transistor coupling to the second node of the first transistor, and a third node of the second transistor;
a comparator coupling to the first transistor and the second transistor, and configured to generate a comparison signal in response to a comparison of a voltage at the first node of the first transistor and a voltage at the first node of the second transistor; and
a voltage adjustment circuit coupling to the reference current source and the first transistor, and comprising a third transistor and a conductive device coupling to the third transistor;
wherein the voltage adjustment circuit is configured to:
receive the comparison signal; and
adjust a voltage at the first node of the first transistor to approach a voltage at the first node of the second transistor according to the comparison signal;
wherein the output current is equal to the reference current multiplied by a factor, and the factor is determined by a size ratio between the first transistor and the second transistor.

2. The driving circuit of claim 1, wherein the comparator comprises an amplifier, the amplifier comprises two inputs coupling to the first node of the first transistor and the first node of the second transistor respectively, and an output coupling to the voltage adjustment circuit.

3. The driving circuit of claim 1, wherein the comparison signal is generated by multiplying the voltage difference between the first node of the second transistor and the first node of the first transistor by a gain.

4. The driving circuit of claim 1, wherein the third transistor comprises a first node of the third transistor coupling to the reference current source, a second node of the third transistor coupling to the comparator to receive the comparison signal, and a third node of the third transistor coupling to the first node of the first transistor.

5. The driving circuit of claim 1, wherein the third transistor comprises a first node of the third transistor coupling to the second node of the first transistor and the second node of the second transistor.

6. The driving circuit of claim 1, wherein the conductive device can be a variable resistor coupling to the third transistor in parallel and controlled by analog or digital method.

7. The driving circuit of claim 1, wherein the conductive device can be a sixth transistor coupling to the third transistor in parallel.

8. The driving circuit of claim 1, wherein a control signal can be applied to one of the nodes of the third transistor through the conductive device.

9. The driving circuit of claim 1, wherein the voltage adjustment circuit couples to the second node of the first transistor and is configured to adjust a voltage at the second node of the first transistor according to the comparison signal.

10. The driving circuit of claim 1, further comprising a fourth transistor which is configured as a switch to control connection and disconnection between the driving circuit and the device.

11. The driving circuit of claim 1, further comprising a voltage shifter coupling to the device and the second transistor, wherein the voltage shifter is configured to adjust a voltage at the first node of the second transistor by shifting a voltage at an output of the driving circuit.

12. The driving circuit of claim 11, wherein the voltage shifter comprises a fourth transistor, and a control signal is applied on a second node of the fourth transistor to control the voltage difference between a first node and a third node of the fourth transistor.

13. The driving circuit of claim 12, further comprising a fifth transistor coupling to the fourth transistor to reduce a voltage drop induced by the fourth transistor.

14. The driving circuit of claim 1, wherein the factor is determined by a size ratio of a width and a length of the second transistor and the first transistor.

15. The driving circuit of claim 1, wherein the device is a light-emitting device.

16. The driving circuit of claim 1, wherein the third node of the first transistor and the third node of the second transistor are coupled to a common voltage.

17. A system configured to emit a light, comprising:
a light-emitting device;
a driving circuit coupling to the light-emitting device and configured to provide an output current to drive the light-emitting device, wherein the driving circuit comprises:
a reference current source configured to provide a reference current;
a first transistor comprising a first node, a second node, and a third node;
a second transistor comprising a first node of the second transistor, a second node of the second transistor coupling to the second node of the first transistor, and a third node of the second transistor;
a comparator coupling to the first transistor and the second transistor, and configured to generate a comparison signal in response to a comparison of a voltage at the first node of the first transistor and a voltage at the first node of the second transistor; and
a voltage adjustment circuit coupling to the reference current source and the first transistor, and comprising a third transistor and a conductive device coupling to the third transistor;
wherein the voltage adjustment circuit is configured to:
receive the comparison signal; and
adjust a voltage at the first node of the first transistor to approach a voltage at the first node of the second transistor according to the comparison signal;
wherein the output current is equal to the reference current multiplied by a factor, and the factor is determined by a size ratio between the first transistor and the second transistor.

18. The system of claim 17, wherein the comparator comprises an amplifier, and the amplifier comprises two inputs coupling to the first node of the first transistor and the first node of the second transistor respectively, and an output coupling to the voltage adjustment circuit.

19. The system of claim 17, wherein the comparison signal is generated by multiplying the voltage difference between the first node of the second transistor and the first node of the first transistor by a gain.

20. A driving circuit configured to provide an output current to drive a device, comprising:
a reference current source configured to provide a reference current;
a first transistor comprising a first node, a second node, and a third node;
a second transistor comprising a first node of the second transistor, a second node of the second transistor coupling to the second node of the first transistor, and a third node of the second transistor;
a comparator coupling to the first transistor and the second transistor, and configured to generate a comparison signal in response to a comparison of a voltage at the first node of the first transistor and a voltage at the first node of the second transistor; and
a PMOS transistor coupling to the reference current source and the first transistor;
wherein the PMOS transistor is configured to:
receive the comparison signal; and
adjust a voltage at the first node of the first transistor to approach a voltage at the first node of the second transistor according to the comparison signal;
wherein the output current is equal to the reference current multiplied by a factor, and the factor is determined by a size ratio between the first transistor and the second transistor.
